(19) United States
(12) Patent Application Publication
(10) Pub. No.: US 2010/0289129 A1
(43) Pub. Date: Nov. 18, 2010

(54) COPPER PLATE BONDING FOR HIGH PERFORMANCE SEMICONDUCTOR PACKAGING

(76) Inventor: SATYA CHINNUSAMY, San Jose, CA (US)

Correspondence Address: O''Melveny & Myers LLP;IP&T Calendar Department LA-13-A7, 400 South Hope Street, Los Angeles, CA, 90071-2899, US

(21) Appl. No.: 12/779,805

(22) Filed: May 13, 2010

Related U.S. Application Data
(60) Provisional application No. 61/178,207, filed on May 14, 2009.

(51) Int. Cl. H01L 23/52; H01L 21/60

(52) U.S. Cl. 257/676; 438/107; 438/123; 257/E21.506; 257/E23.141; 257/E23.169

(57) ABSTRACT

A bonding plate forms high-performance, low-resistance interconnections between integrated circuit die and an electronic package lead frame. The bonding plate is made from copper, aluminum, or metalized silicon and is processed using standard semiconductor fabrication techniques to apply solder bumps and, optionally, copper pillars. The bonding plates are singulated from a wafer and applied to the die package using standard pick-and-place and solder reflow equipment and processes. This achieves high performance interconnect at low cost without the need for specialized tooling.

### RELATED APPLICATION DATA

This application claims the benefit, pursuant to 35 U.S.C. §119(e), of U.S. provisional application Ser. No. 61/178,207, filed May 14, 2009.

### BACKGROUND OF THE INVENTION

1. Field of the Invention

The present invention pertains to the field of semiconductor packaging, and more particularly, to an apparatus and method for bonding semiconductor chips to a package lead frame using a copper plate with solder bumps or copper pillars with solder bumps to create low-resistance bonds capable of carrying large electrical currents.

2. Description of Related Art

It is well known in the art to bond semiconductor chips to traces on a printed circuit board (“PCB”) or a package lead frame using gold, copper, or aluminum wires or ribbons. The size of the wires used in the bonding process is dictated by the magnitude of the current the bond wires will be required to carry. For high current applications, particularly those that employ metal-oxide-semiconductor-field-effect-transistor (MOSFET) technology, standard bond wires do not provide sufficiently low resistance to effectively handle the large currents. Manufacturers of high-performance MOSFET circuits have thus looked to other methods of die bonding. For example, some have suggested clip bonding, as disclosed in U.S. Pat. No. 6,870,254 to Estacio & Quinones. Clip bonding requires that a copper clip be specifically designed and fabricated for a particular die. A custom metal clip is treated with solder paste, placed on top of the die to be bonded, and the assembly is reflowed to make the connections between the chip and the leadframe. While effective, clip bonding is very expensive because it requires custom clip design and fabrication for each die design, special tooling, and multiple assembly steps.

Thus, it would be desirable to provide a die bonding apparatus and method that can support the large currents and low-resistance interconnects required by modern MOSFET designs while overcoming the expense and manufacturing complexity of alternative approaches such as clip bonding.

### SUMMARY OF THE INVENTION

The present invention is directed to a low-cost, high-performance bonding plate for providing electrical and mechanical interconnections between one or more integrated circuit die and a lead frame of an electronic package carrying the die. The bonding plate is preferentially created from a wafer of starting material using standard semiconductor fabrication processes in order to reduce cost and avoid the need for specialized tooling.

In one embodiment of a bonding plate in accordance with the present invention, the starting material is a copper wafer large enough to include many bonding plates. The wafer is processed using standard semiconductor procedures to apply solder bumps at locations at which electrical and mechanical connections are desired. The wafer may then be coated with a protective UV tape or other protective film to protect the solder bumps while the wafer is singulated using standard wafer scribing and cutting techniques. The protective film is then removed from the singulated bonding pads, and standard pick-and-place equipment can be used to place the bonding plates in position on a die mounted in a lead package. The package is then solder reflowed in order to make electrical and mechanical connection between the bonding plate and the die and package lead frame. The bonding plates provide a high-current-carrying capacity that exceeds that of standard bonding wires and thus improves reliability.

In another embodiment of a bonding pad in accordance with the present invention, the bonding plate may be manufactured from aluminum or any other suitable conductive metal. Alternatively, the bonding plate may be formed from a silicon wafer that has been coated with a metallization later.

An embodiment of a bonding plate in accordance with the present invention may include solder bumps of a uniform height, making it suitable for connecting structures with bonding pads disposed in a single horizontal plane. Alternatively, in order to connect structures that lie in different planes, the bonding plate may be configured with solder bumps at different heights. For example, the bonding plate may be processed to include copper pillars topped with solder bumps as well as solder bumps located directly on the surface of the bonding plate. This provides two or more bonding heights for connecting one or more die to a package lead frame even when they do not lie in the same plane.

An embodiment of a bonding plate in accordance with the present invention may be used to connect a single integrated circuit die to a package lead frame. A bonding plate may also be used to connect a first integrated circuit die to a second die. Similarly, a bonding plate may be used to connect a first die, a second die, and a package lead frame, or any number of other structures necessary for electronic packaging.

In another embodiment of a bonding plate in accordance with the present invention, the bonding plate is covered with an insulating film such as polyimide in order to prevent it from unintentionally shorting to structures within the electronic package.

Those skilled in the art will recognize additional embodiments and adaptations of the disclosed invention that are useful in the packaging of electronic integrated circuits, and such variations would also fall within the scope and spirit of the present invention. The invention is further described with reference to the attached figures, which are first described briefly below.

### BRIEF DESCRIPTION OF THE DRAWINGS

FIGS. 1a-1d are views of an embodiment of a bonding plate in accordance with the present invention including solder bumps and bumped copper pillars;

FIG. 2 is a cross section of a device package incorporating a bonding plate assembly in accordance with an embodiment of the present invention;

FIG. 3 is a drawing of a wafer that is processed according to a method in accordance with the present invention to manufacture plate assemblies for bonding die within electronic packages; and

FIG. 4 is a drawing of an alternative embodiment of a plate assembly illustrating that connections may be made between devices lying in multiple different planes.

### DETAILED DESCRIPTION OF THE PREFERRED EMBODIMENT

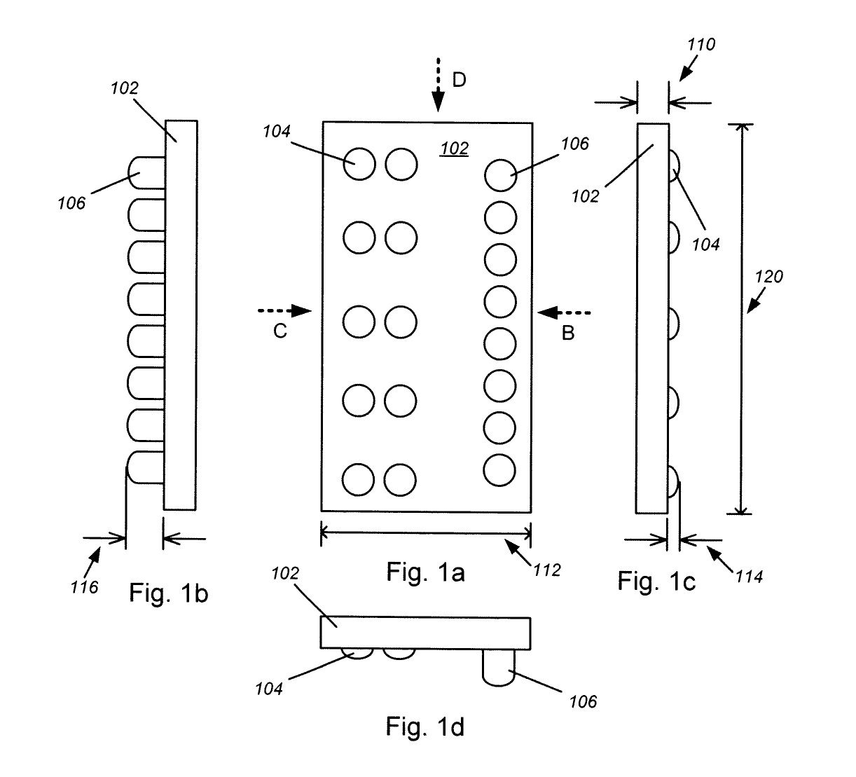

The invention provides an apparatus and method for bonding a semiconductor die to a package lead frame or PCB. In a preferred embodiment of a bonding assembly in accordance with the present invention, a copper plate is processed to add solder bumps in a suitable configuration for making contact with die pads and lead frame traces. FIGS. 1a-1d depict an exemplary bonding plate in accordance with an embodiment of the present invention. FIG. 1a is a plan view of a representative bonding plate 102. The bonding plate 102 is preferentially made from copper, but may be constructed from a different metal, such as aluminum. It may also be constructed from a silicon wafer substrate on which a metal is deposited. The plate in this embodiment is approximately 1.37 mm in width, along the dimension line indicated at element 112. Of course, other widths are possible and would also fall within the scope and spirit of the present invention.

The plate 102 is processed to add solder bumps 104 as circuit connection elements. In order to accommodate connections in more than one plane, some circuit connection elements may comprise copper pillars having solder bumps 106. The structure of copper pillar bumps and a method of fabricating them are disclosed in U.S. Pat. No. 6,413,404 to Ihara, et al., which is herein incorporated by reference.

FIG. 1b is a side view of plate 102 along the direction indicated by arrow B. This figure shows the typical height of the copper pillar bumps 106 at dimension 116. In this particular embodiment, the height of the copper pillar bumps is 0.220 mm, although other heights are also possible and would fall within the scope and spirit of the present invention.

FIG. 1c is a side view of plate 102 along the direction indicated at C in FIG. 1a. From this perspective, the typical height of the solder bumps 104 can be seen by dimension line 114 to be 0.07 mm. However, other dimensions for the solder bumps are possible and would fall within the scope and spirit of the present invention. The typical thickness of the copper plate 102 is given by dimension 110, which is 0.225 mm in this embodiment. Again, other thicknesses are possible, depending on the details of the particular die and package used.

FIG. 1d is an edge view of plate 102 along the direction indicated at D in FIG. 1a. In this view, the relative heights of the solder bumps 104 and the copper pillars 106 can be seen, and the advantages of using such a plate for bonding die to pads lying in different planes should be readily apparent to one skilled in the art. The relative heights of the bumps 104 and pillars 106 may be adjusted as needed for the particular application. Although the embodiment shown is suitable for connecting electrical pads in two different planes, the invention is not limited to connections made in two planes. A plate in accordance with the present invention may comprise only solder bumps or only pillars configured to connect pads lying in the same plane. Alternatively, a plate in accordance with the present invention may include bumps and pillars of varying height for connecting pads lying in three or more different planes.

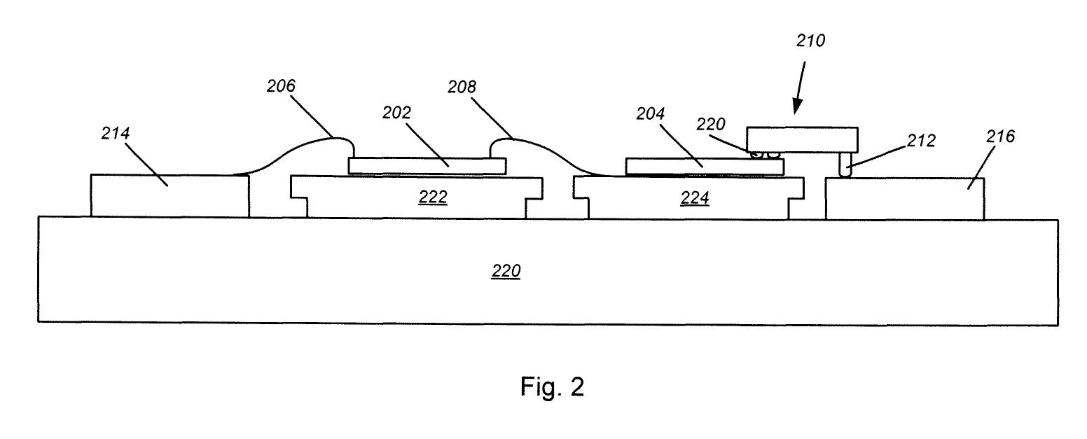

FIG. 2 is a cross section of an electronic package employing a plate in accordance with an embodiment of the present invention to connect a die to a lead frame. The package body 220 includes portions of lead frames 214 and 216 and die-attach pedestals 222 and 224. In this example, a die 202 is wirebonded using conventional wirebonds 206 and 208 to lead frame 214 and to die-attach pedestal 224, respectively. Die 204, on the other hand, is bonded to lead frame 216 using a plate assembly 210 in accordance with an embodiment of the present invention. The plate assembly 210 is configured similarly to the embodiment shown in FIGS. 1a-1d and includes solder bumps 220 and copper pillars 212 to enable a connection between the die 204 at a first height with a lead frame 216 at a second height. The relatively large cross section of the solder bumps and copper pillars, as well as the structure of the plate itself provide a high-current, low-resistance path between the die 204 and the lead frame 216.

The solder bumps 220 on the plate assembly 210 are produced using a flip-chip bumping process well known in the art. During the package assembly process, the die 202 and 204 are mounted on the pedestals 222 and 224 using a standard flip chip process. Solder flux paste is applied to the die pads and lead frame pads using conventional processing techniques. The prepared plate assembly 210 is then put in place by standard pick-and-place equipment such that the solder bumps and pillars are in contact with the solder flux paste. During standard reflow processing, the entire package is heated, and the solder melts, establishing electrical and mechanical connections between the die 204, the plate assembly 210, and the lead frame 216. The use of standard processing techniques makes use of a bonding plate in accordance with the present invention a very cost-effective and robust solution to the problem of die connection and packaging.

In fabricating the plate assembly 210, multiple masking methods are used to achieve the multilayer bumps that allow the plate assembly to connect devices in different planes. To prevent the metal plate from touching the die, protective coatings may be applied to one or both sides of the plate assembly. For example, polyimide coating may be used to create a protective surface on the plate assembly 210.

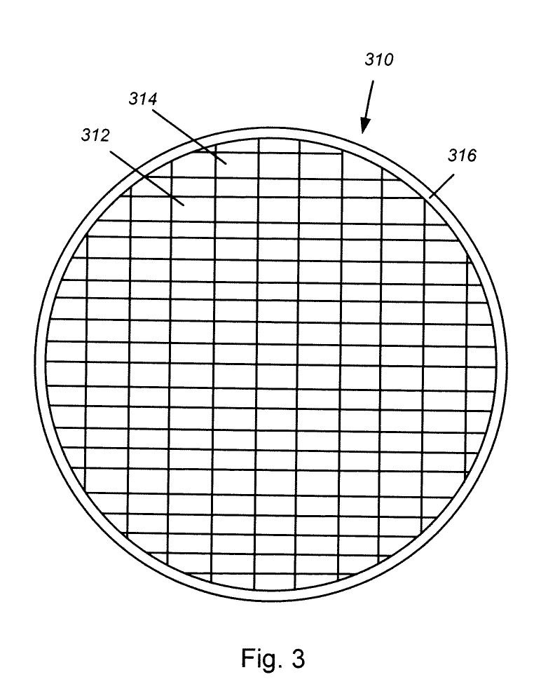

A first method of fabricating a plate assembly in accordance with an embodiment of the invention starts with a metal plate that has already been thinned to the required thickness but that may be large enough to contain multiple plate assemblies. FIG. 3 is a schematic drawing of a large metal wafer from which multiple plate assemblies may be manufactured. The metal wafer 310 is divided into multiple plates, e.g., 312, and 314. An edge exclusion region 316 is defined around the perimeter of the metal wafer 310. Solder bumps and copper pillars are then applied to the metal wafer 310 using standard processing techniques just as if the metal wafer were a standard semiconductor wafer that was being bumped for flip chip connections. Alternatively, the wafer 310 may be a silicon wafer that has been coated with a conductive metal using standard wafer processing techniques familiar to those skilled in the art.

In an alternative embodiment in accordance with the present invention, the thickness of the starting metal or Silicon-metal wafer 310 may be thicker than the final desired plate thickness. Using a thick starting wafer may be preferable during the bumping process for ease of handling and to ensure good planarity. After processing, the wafer may then be ground to the desired thickness using conventional wafer thinning procedures, such as wafer grinding. During the thinning process, ultra-violet (“UV”) tape may be applied to the surface of the wafer to protect the bumps and pillars from damage. After grinding, the UV tape is removed by exposing the wafer to UV light.

Whether the starting with a thin or thick wafer, UV tape is then applied to the wafer to protect it and hold it together during the sawing process used to separate the individual plates, e.g., 312 and 314. A conventional wafer sawing process is then used for singulation of the plates. The sawing machine is programmed to the required x and y dimensions for separating the plates, and a circular blade cuts through the metal surface but leaves the UV tape intact. The UV tape is then removed by exposure to UV light. A pick and place machine is then used to pick up the separated plates and to place them onto the desired locations on the package lead frame by flipping them once so that the bump side faces down and contacts the die and lead frame desired to be bonded. The die and lead frames will have been processed with a solder flux mask to aid the reflowing of the bumped solder on the plates and copper pillars of the plate assembly. The entire package assembly is then sent through the reflow machine to make the contact rigid. The full assembly can then be further processed as needed, for example, by adding wire bonds to the connections that do not require the high-performance interconnect provided by the plates of the present invention.

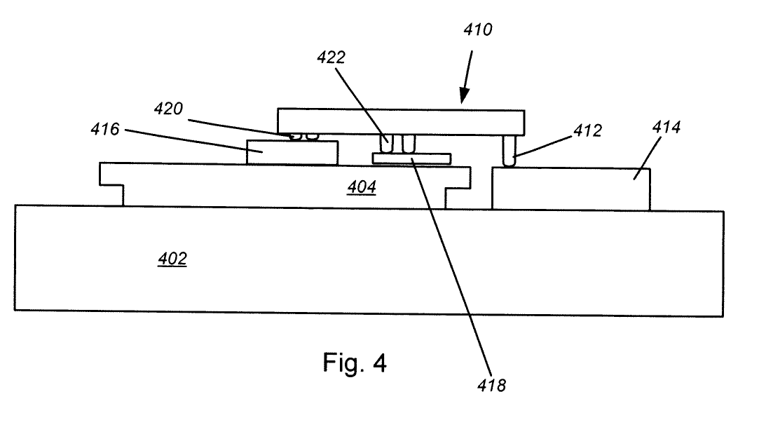

FIG. 4 is an illustration of another embodiment of a plate in accordance with the present invention. In this embodiment, a plate 410 has been processed to enable connections to be made between devices in three different planes. For example, a thick die 416 and a thin die 418 are both mounted on a pedestal 404 of a chip package 402. Both the thick die 416 and the thin die 418 are desired to be connected to the lead frame 414. A single plate assembly 410 may be processed to include solder bumps 420, bumped copper pillars of a first height 422, and bumped copper pillars of a second, greater height 412 in order to enable simultaneous connections to be made in three separate planes. Of course, more or fewer than three heights of bumps could be provided according the specific packaging needs, and plates accommodating any number of different bump heights would fall within the scope and spirit of the present invention.

The invention provides a cost-effective and robust solution to creating low-resistance bonds for packaging die, and it should be clear to those skilled in the art that certain advantages of the invention have thereby been achieved. Other advantages, applications, and modifications of the invention may also be evident to those skilled in the art and would also fall within the scope and spirit of the present invention. The invention is solely defined by the following claims.

What is claimed is:

1. A bonding plate configured to provide electrical and mechanical connections to at least one integrated circuit die mounted within an electronic package, wherein the bonding plate includes:
a planar metallic surface providing conductive current paths; and
a plurality of electrical and mechanical connection points at least partially comprised of a solder material, wherein the solder material is applied to the bonding plate using a solder bumping process;
wherein at least one of the plurality of electrical and mechanical connection points is configured to attach to a bonding pad of the at least one integrated circuit die.

2. The bonding plate of claim 1, wherein at least one of the plurality of electrical and mechanical connection points is configured to attach to a lead frame of the electronic package such that the bonding plate provides a conductive path between the at least one integrated circuit die and the lead frame.

3. The bonding plate of claim 1, wherein at least one of the plurality of electrical and mechanical connection points is configured to attach to a second integrated circuit die mounted within the electronic package such that the bonding plate provides a conductive path between the at least one integrated circuit die and the second integrated circuit die.

4. The bonding plate of claim 1, wherein a first one of the plurality of electrical and mechanical connection points is configured to attach to a lead frame of the electronic package and wherein a second one of the plurality of electrical and mechanical connection points is configured to attach to a second integrated circuit die mounted within the electronic package such that the bonding plate provides a conductive path between the at least one integrated circuit die, the second integrated circuit die, and the lead frame of the electronic package.

5. The bonding plate of claim 1, wherein the bonding plate is comprised of copper.

6. The bonding plate of claim 1, wherein the bonding plate is comprised of aluminum.

7. The bonding plate of claim 1, wherein the bonding plate is comprised of a silicon substrate with a metallic layer deposited thereon.

8. The bonding plate of claim 1, wherein the bonding plate is coated with an insulating film.

9. The bonding plate of claim 8, wherein the insulating film comprises a polyimide material.

10. The bonding plate of claim 1, wherein at least some of the plurality of electrical and mechanical connection points comprise copper pillars having solder bumps formed thereon.

11. The bonding plate of claim 1, wherein the at least one of the plurality of electrical and mechanical connection points is attached to a bonding pad of the at least one integrated circuit die using an automated pick-and-place apparatus and a solder reflow apparatus.

12. The bonding plate of claim 1, wherein the plurality of electrical and mechanical connection points lie in a single plane.

13. The bonding plate of claim 1, wherein the plurality of electrical and mechanical connection points lie in more than one plane.

14. A method of interconnecting integrated circuit die and lead frames within an electronic package comprising the steps of:
mounting at least one integrated circuit die in a flip-chip configuration;
forming a bonding plate according to the steps of:
applying solder bumps to a wafer having a metallic surface and comprising a plurality of bonding plates;
applying a protective film to the wafer comprising a plurality of bonding plates;
singulating the bonding plate having solder bumps from the wafer comprising a plurality of bonding plates; and
removing the protective film from the bonding plate;
attaching the bonding plate to the at least one integrated circuit according to the steps of:
automatically picking up and placing the bonding plate in position such that at least one of the solder bumps on the bonding plate contacts a pad on the at least one integrated circuit using a pick-and-place apparatus; and
reflowing the electronic package to form a mechanical and electrical connection between the bonding plate and the at least one integrated circuit.

15. The method of claim 14 wherein the step of applying solder bumps further comprises creating a copper pillar on the bonding plate.

16. The method of claim 14 wherein the step of attaching the bonding plate further comprises attaching the bonding plate to a second integrated circuit die mounted within the electronic package such that the bonding plate forms an electrical connection between the at least one integrated circuit and the second integrated circuit.

17. The method of claim 16 further including the step of attaching the bonding plate to a lead frame of the electronic package such that the bonding plate forms an electrical connection between the at least one integrated circuit, the second integrated circuit, and the lead frame.

18. The method of 16 wherein the at least one integrated circuit die and the second integrated circuit die do not lie in the same plane.

19. The method of claim 17 wherein the at least one integrated circuit die, the second integrated circuit die and the lead frame each lies in a different plane.

20. The method of claim 14, wherein the step of forming the bonding plate further including the step of grinding the wafer down to a desired thickness before singulating the bonding plate from the wafer.

21. The method of claim 14 wherein the step of applying a protective film includes applying an ultraviolet (UV) tape, and wherein the step of removing the protective film includes exposing the bonding plate to ultraviolet light.
